(19) United States
(12) Patent Application Publication
(10) Pub. No.: US 2025/0279390 A1
(43) Pub. Date: Sep. 4, 2025

(54) METHOD FOR MANUFACTURING SEMICONDUCTOR PACKAGE DEVICE

(71) Applicant: TAIWAN SEMICONDUCTOR MANUFACTURING COMPANY, LTD., Hsinchu (TW)

(72) Inventors: Yun-Fang WU, Hsinchu (TW); Yi Chen HO, Hsinchu (TW)

(73) Assignee: TAIWAN SEMICONDUCTOR MANUFACTURING COMPANY, LTD., Hsinchu (TW)

(21) Appl. No.: 18/592,741

(22) Filed: Mar. 1, 2024

(51) Int. Cl. H01L 23/00

(52) U.S. Cl. CPC H01L 24/80; H01L 2224/80006; H01L 2224/80011; H01L 2224/80013; H01L 2224/80895; H01L 2224/80896; H01L 2924/35121

(57) ABSTRACT

A method for manufacturing a semiconductor package device includes: forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer; treating the first and second semiconductor structures with an acidic reactant including an acid, so that metal oxide formed on each of the first conductive bonding feature and the second conductive bonding feature is reduced to pure metal; and bonding the first semiconductor structure to the second semiconductor structure so as to permit the first dielectric bonding layer to be bonded to the second dielectric bonding layer and to permit the first conductive bonding feature to be bonded to the second conductive bonding feature.

### BACKGROUND

In recent years, the advancement in semiconductor technology may go beyond the prediction of Moore's law. In semiconductor packing technology, chip on wafer (CoW) and wafer on wafer (WoW) bonding processes are currently performed for packaging a small outline integrated circuit (SoIC) (without an underfill loop process), and play a key role in the production yield of the SoIC. In the CoW and WoW processes, bonding strength and compactness of two semiconductor dies in the SoIC are crucial. In order to increase the production yield of the SoIC, there is a need to improve the bonding strength and the compactness of the two semiconductor dies in the SoIC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor package device in accordance with some embodiments.

FIGS. 2 to 11 are schematic views illustrating some intermediate stages of the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

In a small outline integrated circuit (SoIC), fusion bonding and hybrid bonding are two bonding methods respectively used to bond one semiconductor die (or chip) and a carrier wafer and to bond two semiconductor dies (or chips) together. Currently, when the two semiconductor dies are bonded together through a bonding method (e.g., hybrid bonding), opening and/or delamination may be formed at the interface between the bond pad metals (BPMs), which may adversely affect production yield of the SoIC. Formation of the opening or the delamination may result from poor thermal expansion of the BPMs or poor bonding strength between the BPMs, both of which may be caused by oxidation of a bonding surface of each of the BPMs. Therefore, in a bonding process for bonding the two semiconductor dies in the SoIC, there is a need to efficiently reduce oxidation of the BPMs, so as to avoid poor thermal expansion of the BPMs, and to increase the bonding strength between the BPMs.

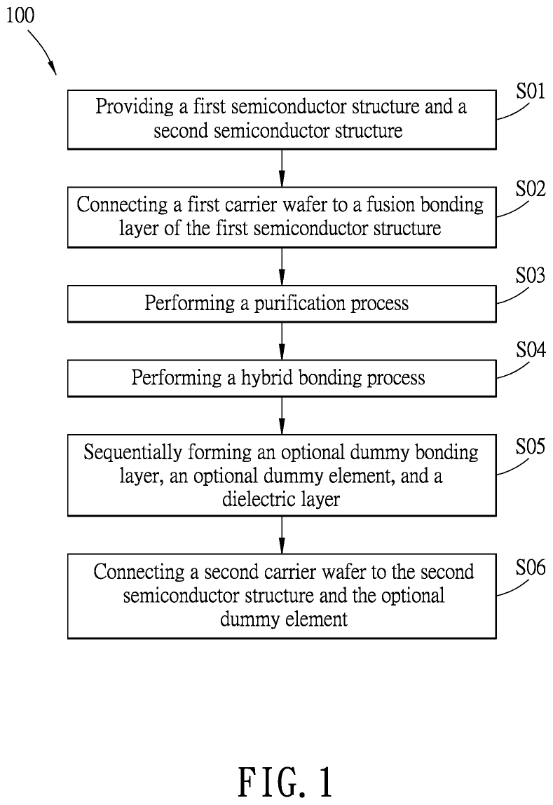

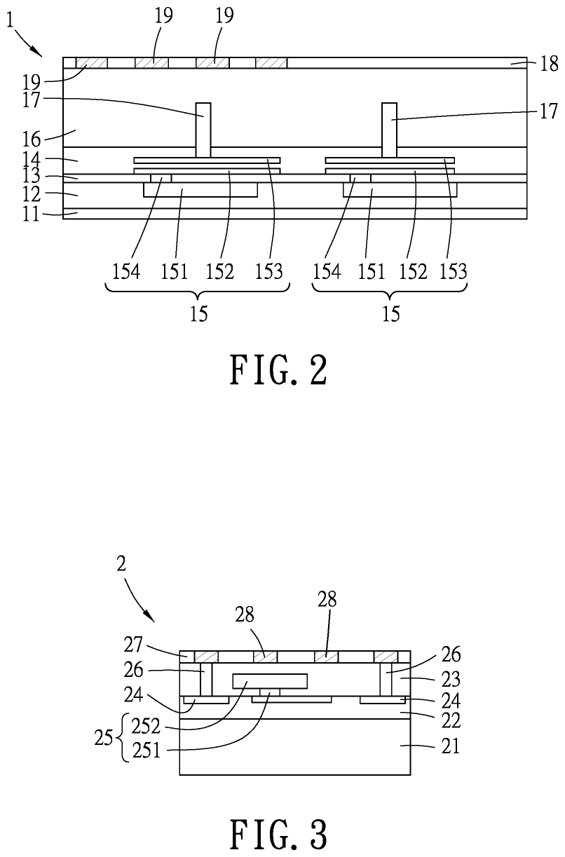

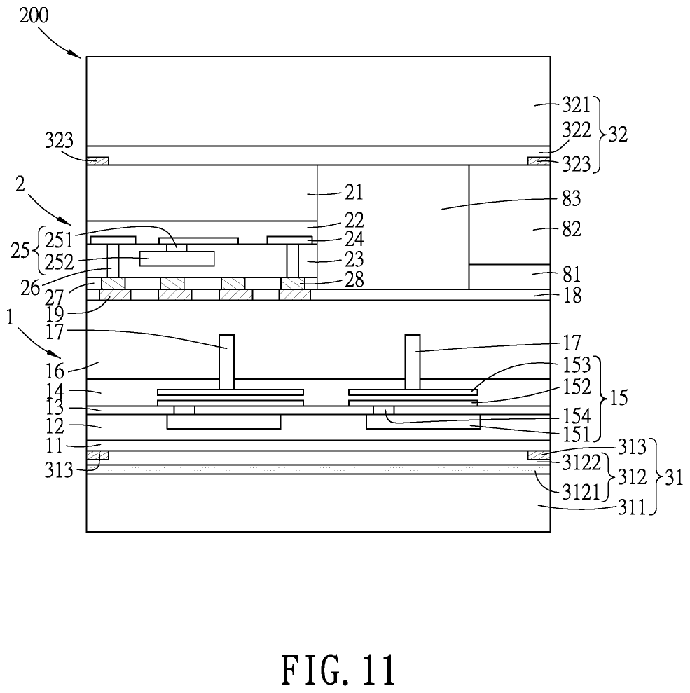

The present disclosure is directed to a semiconductor package device and a method for manufacturing the same. FIG. 1 is a flow diagram illustrating a method 100 for manufacturing a semiconductor package device 200 shown in FIG. 11 in accordance with some embodiments. FIGS. 2 to 10 illustrate schematic views of some intermediate stages of the method 100. Some portions may be omitted in FIGS. 2 to 10 for the sake of brevity. Additional steps can be provided before, after or during the method 100, and some of the steps described herein may be replaced by other steps or be eliminated.

Referring to FIG. 1 and the example illustrated in FIGS. 2 and 3, the method 100 begins at step S01, where a first semiconductor structure 1 (see FIG. 2) and a second semiconductor structure 2 (see FIG. 3) are independently provided. In some embodiments, each of the first semiconductor structure 1 and the second semiconductor structure 2 is a semiconductor die or a semiconductor chip.

As shown in FIG. 2, the first semiconductor structure 1 includes a fusion bonding layer 11, a dielectric oxide layer 12, a first inter-layer dielectric (ILD) layer 13, a first inter-metal dielectric (IMD) layer 14, a plurality of first metallization structures 15, a first semiconductor device 16, a plurality of through vias 17, a first dielectric bonding layer 18, and a plurality of first conductive bonding features 19.

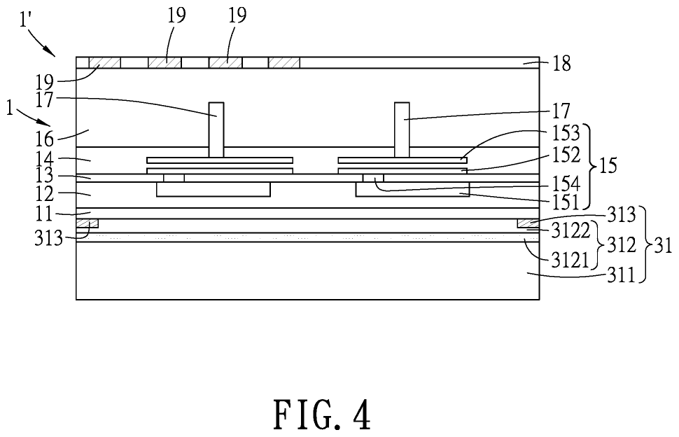

The fusion bonding layer 11 may be made of a dielectric oxide-based material, for example, but not limited to, silicon oxide. Other suitable materials for the fusion bonding layer 11 are also within the contemplated scope of the present disclosure. The fusion bonding layer 11 is connected to a fusion bonding layer 312 of a first carrier wafer 31 (which will be described hereinafter with reference to FIG. 4).

The dielectric oxide layer 12 is disposed on the fusion bonding layer 11. The dielectric oxide layer 12 may be made of a dielectric oxide-based material, for example, but not limited to, silicon oxide, carbon-doped silicon oxide, nitrogen-doped silicon oxide, or combinations thereof. Other suitable materials for the dielectric oxide layer 12 are also within the contemplated scope of the present disclosure.

The first ILD layer 13 is disposed on the dielectric oxide layer 12 opposite to the fusion bonding layer 11. The first ILD layer 13 may include, for example, but not limited to, phosphosilicate glass (PSG) or silicon oxide. Other suitable materials for the first ILD layer 13 are also within the contemplated scope of the present disclosure.

The first IMD layer 14 is disposed on the first ILD layer 13 opposite to the dielectric oxide layer 12. The first IMD layer 14 may include, for example, but not limited to, silicon oxide, silicon nitride, or spin-on glass (SOG). Other suitable materials for the first IMD layer 14 are also within the contemplated scope of the present disclosure.

Each of the first metallization structures 15 includes a plurality of first conductive lines 151, 152, 153, and a first conductive via 154. The first conductive line 151 is disposed in the dielectric oxide layer 12, and the first conductive lines 152, 153 are disposed in the first IMD layer 14. The first conductive via 154 is disposed in the first ILD layer 13. In some embodiments, the first conductive lines 151, 152 are connected to each other through the first conductive via 154. Each of the first conductive lines 151, 152, 153 and the first conductive via 154 may be made of a conductive material, for example, but not limited to, aluminum (Al). Other suitable conductive materials for the first conductive lines 151, 152, 153 and the first conductive via 154 are also within the contemplated scope of the present disclosure.

The first semiconductor device 16 is disposed on the first IMD layer 14 opposite to the first ILD layer 13. In some embodiments, the first semiconductor device 16 is a central processing unit (CPU). Other suitable semiconductor devices (e.g., a graphics processing unit (GPU)) for the first semiconductor device 16 are also within the contemplated scope of the present disclosure.

The through vias 17 are disposed in the first IMD layer 14 and the first semiconductor device 16, and are spaced apart from each other. In some embodiments, the through vias 17 may be made of a conductive material, for example, but not limited to, copper (Cu). Other suitable materials for the through vias 17 are also within the contemplated scope of the present disclosure.

The first dielectric bonding layer 18 is disposed on the first semiconductor device 16 opposite to the first IMD layer 14. The first dielectric bonding layer 18 may include, for example, but not limited to, undoped silicate glass (USG), silicon oxynitride (SiON), silicon oxide (SiO₂), or combinations thereof. Other suitable materials for the first dielectric bonding layer 18 are also within the contemplated scope of the present disclosure.

The first conductive bonding features 19 are disposed in the first dielectric bonding layer 18, and are spaced apart from each other. The first conductive bonding features 19 may be made of a conductive material, for example, but not limited to, metal (e.g., copper (Cu) or the like). Other suitable conductive materials for the first conductive bonding features 19 are also within the contemplated scope of the present disclosure. In some embodiments, the first conductive bonding features 19 may be referred to as bond pad metals (BPMs).

As shown in FIG. 3, the second semiconductor structure 2 includes a second semiconductor device 21, a second ILD layer 22, a dielectric layer 23, a plurality of second conductive lines 24, a second metallization structure 25, a plurality of bonding vias 26, a second dielectric bonding layer 27, and a plurality of second conductive bonding features 28.

In some embodiments, the second semiconductor device 21 is a static random access memory (SRAM) device. Other suitable semiconductor memory devices or other suitable semiconductor devices for the second semiconductor device 21 are also within the contemplated scope of the present disclosure.

The second ILD layer 22 is disposed on the second semiconductor device 21. The material for the second ILD layer 22 may be the same as or similar to that for the first ILD layer 13, and thus a detail thereof is omitted for the sake of brevity.

The dielectric layer 23 is disposed on the second ILD layer 22 opposite to the second semiconductor device 21. The dielectric layer 23 may include, for example, but not limited to, tetraethoxysilane (TEOS), silicon oxide, or other suitable dielectric materials. Other suitable materials for the dielectric layer 23 are also within the contemplated scope of the present disclosure.

The second conductive lines 24 are disposed in the second ILD layer 22, and are spaced apart from each other. The material for the second conductive lines 24 may be the same as or similar to that for the first conductive lines 151, 152, 153, and thus a detail thereof is omitted for the sake of brevity.

The second metallization structure 25 is disposed in the dielectric layer 23, and is connected to one of the second conductive lines 24. The second metallization structure 25 may include a second conductive via 251, and a conductive layer 252. The second conductive via 251 interconnects the conductive layer 252 and the one of the second conductive lines 24. The respective materials for the second conductive via 251 and the conductive layer 252 of the second metallization structure 25 may be the same as or similar to those for the first conductive via 154 and the first conductive lines 151, 152, 153 of the first metallization structure 15, and thus details thereof are omitted for the sake of brevity.

The bonding vias 26 are disposed in the dielectric layer 23, are spaced apart from each other, and are respectively connected to remaining ones of the second conductive lines 24. The bonding vias 26 may be made of a conductive material, for example, but not limited to, copper (Cu). Other suitable conductive materials for the bonding vias 26 are also within the contemplated scope of the present disclosure. In some embodiments, the bonding vias 26 may be referred to as bond pad vias (BPVs).

The second dielectric bonding layer 27 is disposed on the dielectric layer 23 opposite to the second ILD layer 22. The second dielectric bonding layer 27 may include, for example, but not limited to, undoped silicate glass (USG), silicon oxide (SiO₂), silicon oxynitride (SiON), or combinations thereof. Other suitable materials for the second dielectric bonding layer 27 are also within the contemplated scope of the present disclosure.

The second conductive bonding features 28 are disposed in the second dielectric bonding layer 27, and are spaced apart from each other. The material for the second conductive bonding features 28 may be the same as or similar to that for the first conductive bonding features 19, and thus a detail thereof is omitted for the sake of brevity. In some embodiments, the second conductive bonding features 28 may be referred to as BPMs.

Referring to FIG. 1 and the example illustrated in FIG. 4, the method 100 then proceeds to step S02, where the fusion bonding layer 312 of the first carrier wafer 31 is connected to the fusion bonding layer 11 of the first semiconductor structure 1 through a fusion bonding process. The first carrier wafer 31 may include a first base 311, the fusion bonding layer 312, and a plurality of first alignment marks 313. The first base 311 may be made of silicon (Si). The fusion bonding layer 312 of the first carrier wafer 31 is disposed on the first base 311. In some embodiments, the fusion bonding layer 312 of the first carrier wafer 31 may include a lower portion 3121 disposed on the first base 311, and an upper portion 3122 disposed on the lower portion 3121 opposite to the first base 311. The lower portion 3121 of the fusion bonding layer 312 of the first carrier wafer 31 may be made of silicon nitride (SiN). The upper portion 3122 of the fusion bonding layer 312 of the first carrier wafer 31 may be made of an oxide-based material (e.g., high density plasma oxide). The first alignment marks 313 are disposed in the upper portion 3122 of the fusion bonding layer 312 of the first carrier wafer 31, and are spaced apart from each other. The first alignment marks 313 may be made of metal, for example, but not limited to, copper (Cu). The first alignment marks 313 are used to establish a precise connection between the first semiconductor structure 1 and the first carrier wafer 31. Other suitable materials for each of the first base 311, the fusion bonding layer 312, and the first alignment marks 313 of the first carrier wafer 31 are also within the contemplated scope of the present disclosure. As shown in FIG. 4, the semiconductor structure obtained after step S02 is denoted by reference numeral 1′.

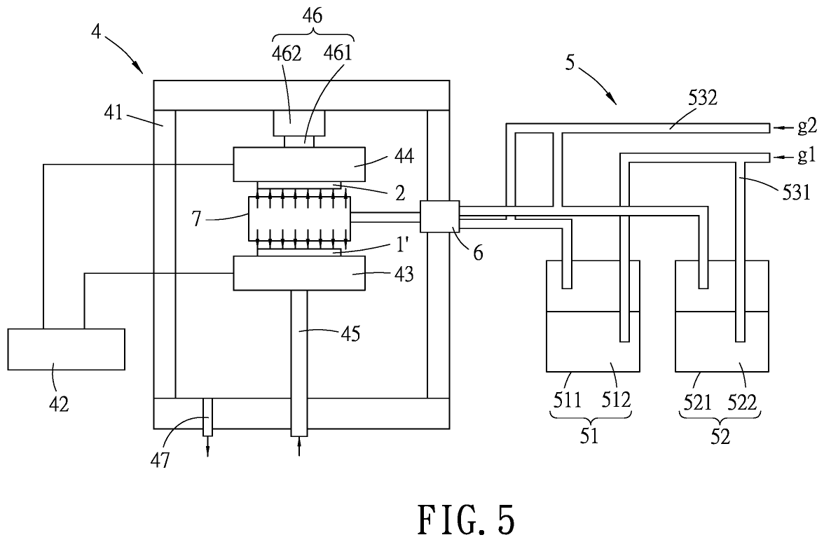

Referring to FIG. 1 and the example illustrated in FIGS. 5 to 8, the method 100 then proceeds to step S03, where a purification process is performed on the semiconductor structure 1′ shown in FIG. 4 and the second semiconductor structure 2 shown in FIG. 3. Step S03 may be performed by exposing the semiconductor structure l′ and the second semiconductor structure 2 to a reducing reactant, so that metal oxide formed on the semiconductor structure 1′ and the second semiconductor structure 2 are reduced to pure metal through a reduction reaction. In some embodiments, the metal oxide formed on the semiconductor structure 1′ may be, for example, but not limited to, cupric oxide (CuO), cuprous oxide (Cu₂O), or a combination thereof. The metal oxide is formed on the first conductive bonding features 19 (made of, for example, but not limited to, copper (Cu)) of the first semiconductor structure 1. In some embodiments, the metal oxide formed on the second semiconductor structure 2 may be, for example, but not limited to, cupric oxide (CuO), cuprous oxide (Cu₂O), or a combination thereof. The metal oxide is formed on the second conductive bonding features 28 (made of, for example, but not limited to, copper (Cu)) of the second semiconductor structure 2.

Step S03 may include the following sub-steps (i) to (iv), and may be performed using a bonding apparatus 4, a reactant supplier assembly 5, a plasma apparatus 6, and a nozzle 7.

The bonding apparatus 4 may include a chamber 41, a stage heater 42, a lower stage 43, an upper stage 44, a lower load port 45, an upper load port 46, and a gas outlet 47. The lower stage 43 and the upper stage 44 are mounted opposite to each other within the chamber 41. The lower stage 43 and the upper stage 44 are respectively provided to permit the semiconductor structure 1′ and the second semiconductor structure 2 to be mounted thereon. In some embodiments, the semiconductor structure 1′ and the second semiconductor structure 2 may be mounted on the upper stage 44 and the lower stage 43, respectively. In some embodiments, the lower stage 43 can be moved upwardly and downwardly in a vertical direction perpendicular to the lower stage 43, and the upper stage 44 can be moved in a horizontal direction parallel to the lower stage 43. The lower load port 45 is connected to the lower stage 43 opposite to the upper stage 44. The upper load port 46 is connected to the upper stage 44 opposite to the lower stage 43. In some embodiments, the upper load port 46 may include a first part 461 and a second part 462. The first part 461 of the upper load port 46 is disposed between the upper stage 44 and the second part 462 of the upper load port 46. The stage heater 42 is connected to the lower stage 43 and the upper stage 44, and is used to supply heat energy to the lower stage 43 and the upper stage 44 during a fusion bonding process and/or a hybrid bonding process, so that a temperature of each of the lower stage 43 and the upper stage 44 increases during the fusion bonding process and/or the hybrid bonding process (which will be described hereinafter).

The reactant supplier assembly 5 may include a first reactant supplier 51, a second reactant supplier 52, a first piping system 531, and a second piping system 532. In some embodiments, the first reactant supplier 51 may include a first tank 511 and an acidic reactant 512 placed in the first tank 511. In some embodiments, the second reactant supplier 52 may include a second tank 521 and an alkaline reactant 522 placed in the second tank 521. In some embodiments, the second piping system 532 is in fluid communication with the first piping system 531.

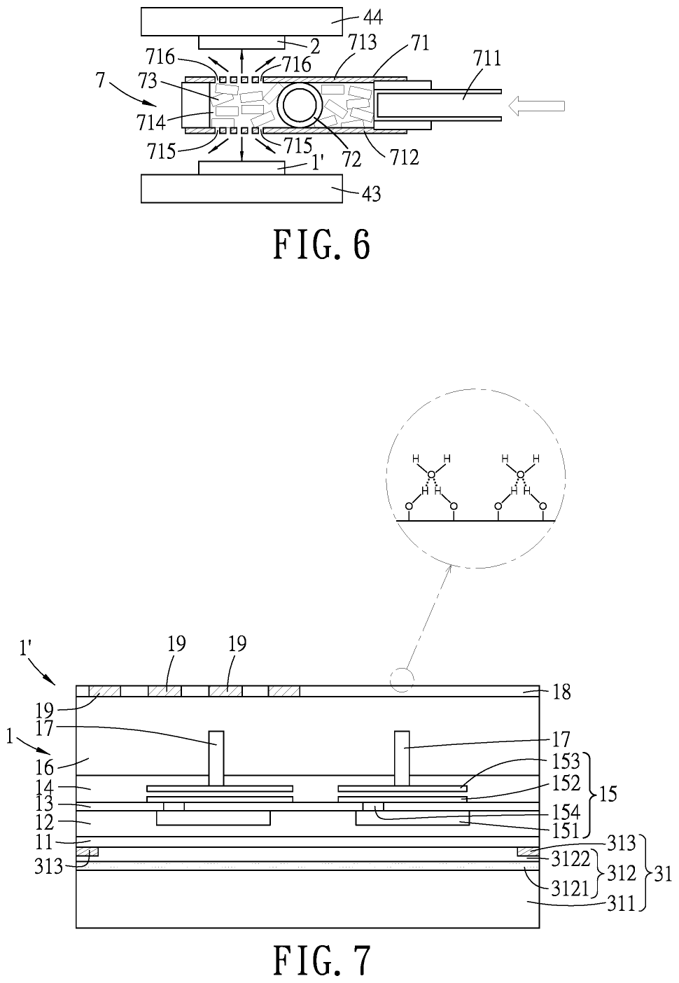

The plasma apparatus 6 includes a plasma chamber (not shown), a plasma generator (not shown), and at least two gas lines (not shown). The plasma generator is coupled to the plasma chamber, and is used to generate a plasma within the plasma chamber. In some embodiments, the plasma generator may be a radio frequency (RF) plasma generator. One of the gas lines of the plasma apparatus 6 is in fluid communication with outlets of the first piping system 531, and the other one of the gas lines of the plasma apparatus 6 is in fluid communication with an inlet 711 of a nozzle body 71 of the nozzle 7 (which will be described hereinafter with reference to FIG. 6). In some embodiments, the plasma apparatus 6 may be, for example, but not limited to, a remote plasma source device. Other suitable plasma devices for the plasma apparatus 6 are also within the contemplated scope of the present disclosure.

As shown in FIG. 6, the nozzle 7 includes the nozzle body 71 and a heater 72. The nozzle body 71 includes the inlet 711, a lower portion 712, an upper portion 713, an accommodating space 714, a plurality of lower openings 715, and a plurality of upper openings 716. The accommodating space 714 is defined between the lower portion 712 and the upper portion 713, and a catalyst 73 is disposed in the accommodating space 714. The lower openings 715 penetrate the lower portion 712. The upper openings 716 penetrate the upper portion 713. The heater 72 is disposed in the accommodating space 714 of the nozzle body 71. In some embodiments, the heater 72 is used to heat the catalyst 73, so as to expedite catalysis initiated by the catalyst 73.

In sub-step (i), the semiconductor structure 1′ and the second semiconductor structure 2 are respectively attached to the lower stage 43 and the upper stage 44 of the bonding apparatus 4, and the first dielectric bonding layer 18 of the first semiconductor structure 1 and the second dielectric bonding layer 27 of the second semiconductor structure 2 face each other.

In sub-step (ii), a first carrier gas (g1) is introduced to the first tank 511 or the second tank 521 through an inlet of the first piping system 531, and delivers the acidic reactant 512 or the alkaline reactant 522 to a corresponding one of the outlets of the first piping system 531. In some embodiments, during introduction of the first carrier gas (g1), a second carrier gas (g2) may be simultaneously introduced to the second piping system 532, and flows into the first piping system 531 to enhance delivery of the acidic reactant 512 or the alkaline reactant 522 to the corresponding one of the outlets of the first piping system 531. In some embodiments, each of the first carrier gas (g1) and the second carrier gas (g2) (which will be introduced to the chamber 41) may be an inert gas. The inert gas is used to maintain the chamber 41 in an inert atmosphere so as to prevent reoxidation of the pure metal formed on the first conductive bonding features 19 of the first semiconductor structure 1 and the pure metal formed on the second conductive bonding features 28 of the second semiconductor structure 2 by the purification process through the reduction reaction. In some embodiments, the inert gas may be, for example, but not limited to, nitrogen (N₂) gas, argon (Ar) gas, helium (He) gas, or combinations thereof. Other suitable inert gases for the first carrier gas (g1) and the second carrier gas (g2) are also within the contemplated scope of the present disclosure. In some embodiments, the acidic reactant 512 includes an acid, and the alkaline reactant 522 includes alkaline water (H₂O) or an alkaline solution. In some embodiments, the acid may be, for example, but not limited to, an organic acid (for example, but not limited to, formic acid (HCOOH), acetic acid (CH₃COOH), or a combination thereof), an inorganic acid (for example, but not limited to, hydrochloric acid (HCl), sulfuric acid (H₂SO₄), or a combination thereof), or a combination thereof. Other suitable acids are also within the contemplated scope of the present disclosure. In some embodiments, the acid may have a hydrogen ion (H⁺) concentration ranging from about 10⁻³ mol/L to about 10⁻⁴ mol/L. In some embodiments, the alkaline solution may be, for example, but not limited to, an ammonia (NH₄OH) aqueous solution, a calcium hydroxide (Ca(OH)₂) aqueous solution, a barium hydroxide (Ba(OH)₂) aqueous solution, a strontium hydroxide (Sr(OH)₂) aqueous solution, a thallium hydroxide (TlOH) aqueous solution, or combinations thereof. In some embodiments, the alkaline solution may have a hydroxide ion (OH⁻) concentration ranging from about 10⁻² mol/L to about 10⁻³ mol/L. Other suitable alkaline solutions are also within the contemplated scope of the present disclosure. When the hydrogen ion (H⁺) concentration of the acid is lower than about 10⁻³ mol/L, the metal oxide formed on the semiconductor structure 1′ (e.g., the metal oxide formed on the first conductive bonding features 19 of the first semiconductor structure 1) and/or the metal oxide formed on the second semiconductor structure 2 (e.g., the metal oxide formed on the second conductive bonding features 28 of the second semiconductor structure 2) may not be efficiently reduced to pure metal, leading to decrease in a bonding strength of a bonding interface between the semiconductor structure 1′ and the second semiconductor structure 2 (for example, a bonding interface of each of the first conductive bonding features 19 of the first semiconductor structure 1 and a corresponding one of the second conductive bonding features 28 of the second semiconductor structure 2). When the hydroxide ion (OH⁻) concentration of the alkaline water (H₂O) or the alkaline solution is lower than about 10⁻² mol/L, the hydroxide ions (OH⁻) formed on a surface of each of the first dielectric bonding layer 18 of the first semiconductor structure 1 and the second dielectric bonding layer 27 of the second semiconductor structure 2 may not be increased sufficiently, such that a bonding strength of a bonding interface between the first dielectric bonding layer 18 and the second dielectric bonding layer 27 may not be enhanced satisfactorily. In some embodiments, a gas flow rate of the acidic reactant 512 may range from about 10 standard cubic centimeters per minute (sccm) to about 150 sccm, and a gas flow rate of the alkaline reactant 522 may range from about 10 sccm to about 150 sccm.

In sub-step (iii), the acidic reactant 512 and the alkaline reactant 522 are separately introduced to the plasma apparatus 6, followed by performing a plasma treatment. In some embodiments, the plasma generation power used in this sub-step may range from about 40 W to about 70 W. In some embodiments, the plasma generation frequency used in this sub-step may range from about 10 MHz to about 50 MHz. After sub-step (iii), each of the acidic reactant 512 and the alkaline reactant 522 is in a dissociated state, and then flows into the inlet 711 of the nozzle body 71. For example, when the acidic reactant 512 is formic acid (HCOOH) and the alkaline reactant 522 is alkaline water (H₂O), the acidic reactant 512 and the alkaline reactant 522 are separately subjected to the plasma treatment, and the acidic reactant 512 is then dissociated into formate ions (HCOO⁻) and hydrogen ions (H⁺) while the alkaline reactant 522 is then dissociated into hydrogen ions (H⁺) and hydroxide ions (OH⁻), which are respectively described by the following chemical equations.

HCOOH→HCOO_{(ads}_{¹}₎+H⁺+e⁻

H₂O→H⁺+OH⁻

Note: ads¹ indicates adsorbed.

In sub-step (iv), the metal oxide formed on the first conductive bonding features 19 of the first semiconductor structure 1 of the semiconductor structure 1′ and the metal oxide formed on the second conductive bonding features 28 of the second semiconductor structure 2 are subjected to a purification treatment with the acid (e.g., the formic acid (HCOOH)) and the dissociated ions (e.g., the formate ions (HCOO⁻) and the hydrogen ions (H⁺)), so that the metal oxide formed on the first conductive bonding features 19 of the first semiconductor structure 1 of the semiconductor structure 1′ and the metal oxide formed on the second conductive bonding features 28 of the second semiconductor structure 2 are reduced to pure metal. In this sub-step, the nozzle 7 moves to a position that is located between the lower stage 43 and the upper stage 44 of the bonding apparatus 4, and the lower openings 715 and the upper openings 716 face the semiconductor structure 1′ and the second semiconductor structure 2, respectively, and then the dissociated ions (e.g., the hydrogen ions (H⁺) formed from the acidic reactant 512 (e.g., the acid) and the alkaline reactant 522 (e.g., the alkaline water (H₂O), the alkaline solution, or the combination thereof), and the acid anions formed from the acidic reactant 512), and the acidic reactant 512 (e.g., the acid) flow out from the lower openings 715 and the upper openings 716 of the nozzle body 71 to react with the metal oxide (e.g., CuO, Cu₂O, or a combination thereof) formed on the first conductive bonding features 19 of the first semiconductor structure 1 of the semiconductor structure 1′ and the metal oxide (e.g., CuO, Cu₂O, or a combination thereof) formed on the second conductive bonding features 28 of the second semiconductor structure 2, so that the metal oxide formed on the first conductive bonding features 19 of the first semiconductor structure 1 of the semiconductor structure 1′ and the metal oxide formed on the second conductive bonding features 28 of the second semiconductor structure 2 are reduced to pure metal (e.g., copper (Cu)). In some embodiments, the alkaline reactant 522 (e.g., the alkaline water (H₂O), the alkaline solution or the combination thereof) is introduced from the second tank 521, through the plasma apparatus 6, into the nozzle body 71, and then flows out from the lower openings 715 and the upper openings 716 of the nozzle body 71, followed by introducing the acidic reactant 512 (e.g., the acid) from the first tank 511, through the plasma apparatus 6, into the nozzle body 71, and then the acidic reactant 512 flows out from the lower openings 715 and the upper openings 716 of the nozzle body 71. In some embodiments, the alkaline reactant 522 is introduced for a time period ranging from about 20 seconds to about 40 seconds. When the alkaline reactant 522 is introduced for a time period shorter than about 20 seconds, the amount of hydroxide ions (OH⁻) formed on a surface of each of the first dielectric bonding layer 18 of the first semiconductor structure 1 and the second dielectric bonding layer 27 of the second semiconductor structure 2 may not be increased sufficiently, such that a bonding strength of a bonding interface between the first dielectric bonding layer 18 and the second dielectric bonding layer 27 may not be enhanced satisfactorily. In some embodiments, the acidic reactant 512 is introduced for a time period ranging from about 30 seconds to about 120 seconds. When the acidic reactant 512 is introduced for a time period shorter than about 30 seconds, the metal oxide may not efficiently reduced to pure metal, resulting in a poor purification effect. In some embodiments, an introduction of the alkaline reactant 522 (e.g., the alkaline water (H₂O), the alkaline solution or the combination thereof) may be omitted.

For example, the purification treatment of cupric oxide (CuO) and cuprous oxide (Cu₂O) (i.e., the metal oxide) with the formic acid (HCOOH, i.e., an acidic reactant) is described by the following chemical equations, in which hydrogen ions (H⁺) are formed from the formic acid (HCOOH) and the alkaline water (H₂O).

Cu₂O+HCOOH_{(g}_{¹}₎→2Cu+H₂O_{(g}_{¹}₎+CO_{2(g}_{¹}₎

Cu—O—H_{(ads}_{²}₎+H_{(rad}_{³}₎→Cu+H₂O

Cu—O+2H_{(rad}_{³}₎→Cu+H₂O

Cu—HCOO_{(ads}_{²}₎+H_{(rad}_{³}₎→Cu+H₂+CO₂

Note: g¹ indicates gas state;
ads² indicates adsorbed; and
rad³ indicates radical.

In some embodiments, after the purification treatment, reaction byproducts (e.g., carbon dioxide (CO₂) gas) are pumped out through the gas outlet 47 of the bonding apparatus 4. In some embodiments, after the purification treatment, the nozzle 7 is moved away from the position that is between the lower stage 43 and the upper stage 44 of the bonding apparatus 4. In some embodiments, the acidic reactant 512 and/or the alkaline reactant 522 which are/is not dissociated in the plasma apparatus 6 may be dissociated in the nozzle 7. In this case, the catalyst 73 in the accommodating space 714 of the nozzle body 71 is helpful for dissociation of the acidic reactant 512 and/or the alkaline reactant 522. In some embodiments, the catalyst 73 may be a precious metal, for example, but not limited to, platinum (Pt). Other suitable precious metals are also within the contemplated scope of the present disclosure.

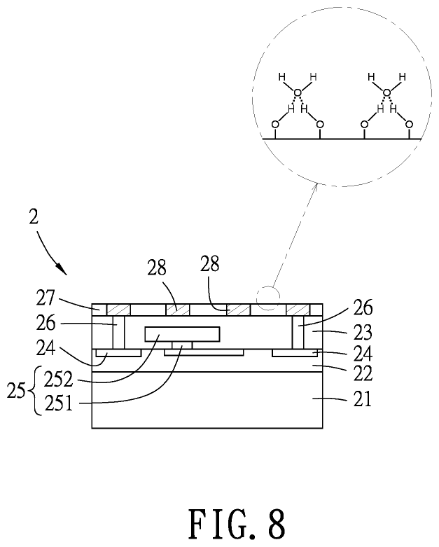

In some embodiments, after this step, the hydroxide ions (OH⁻) which are formed by dissociation of the alkaline reactant 522 and which are present in the chamber 41 may form a chemical bonding on a surface of each of the first dielectric bonding layer 18 of the first semiconductor structure 1 (see FIG. 7) and the second dielectric bonding layer 27 of the second semiconductor structure 2 (see FIG. 8).

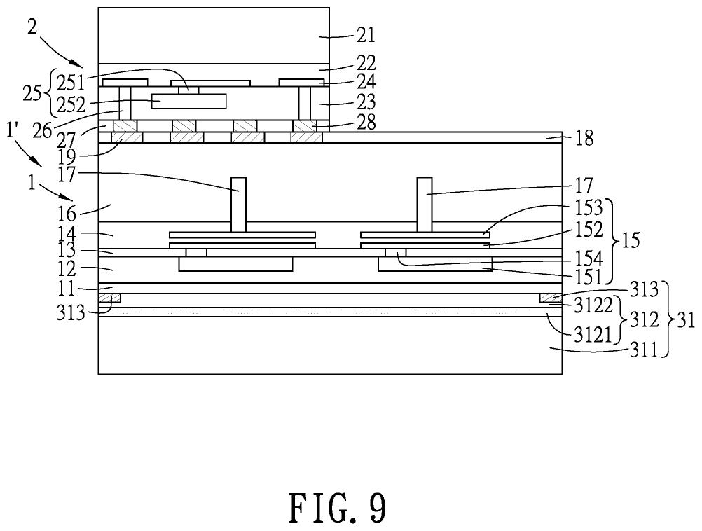

Referring to FIG. 1 and the example illustrated in FIG. 9, the method 100 then proceeds to step S04, where the semiconductor structure 1′ shown in FIG. 7 and the second semiconductor structure 2 shown in FIG. 8 are bonded together (i.e., a hybrid bonding process), so that the first dielectric bonding layer 18 of the first semiconductor structure 1 is bonded to the second dielectric bonding layer 27 of the second semiconductor structure 2, and the first conductive bonding features 19 of the first semiconductor structure 1 are respectively bonded to the second conductive bonding features 28 of the second semiconductor structure 2. In some embodiments, the first dielectric bonding layer 18 of the first semiconductor structure 1 is bonded to the second dielectric bonding layer 27 of the second semiconductor structure 2 through covalent bonding that is formed after a dehydration reaction. In this step, the second semiconductor structure 2 mounted on the upper stage 44 is moved horizontally by the upper load port 46 so as to permit the second conductive bonding features 28 of the second semiconductor structure 2 to be aligned with the first conductive bonding features 19 of the first semiconductor structure 1, and then a bonding load force is applied to the lower load port 45 of the bonding apparatus 4, so as to permit the lower stage 43 and the semiconductor structure 1′ to be moved upwardly, followed by bonding the first semiconductor structure 1 to the second semiconductor structure 2. Step S04 may be performed at a bonding temperature (i.e., the temperature of the lower stage 43 and the upper stage 44 controlled by the stage heater 42). In some embodiments, the bonding temperature ranges from about 180° C. to about 220° C. When the bonding temperature is lower than about 180° C., the first semiconductor structure 1 may not be efficiently bonded to the second semiconductor structure 2. When the bonding temperature is greater than about 220° C., the first semiconductor structure 1 and the second semiconductor structure 2 may be damaged.

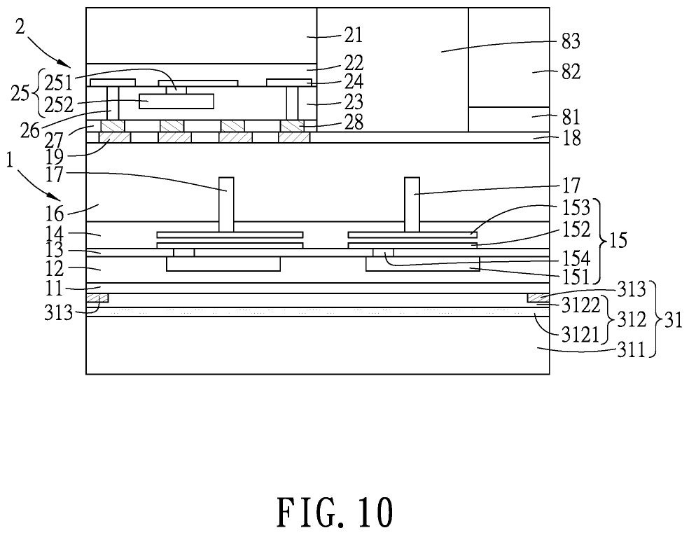

Referring to FIG. 1 and the example illustrated in FIG. 10, the method 100 then proceeds to step S05, where an optional dummy bonding layer 81, an optional dummy element 82, and a dielectric layer 83 are sequentially formed on the structure shown in FIG. 9. The optional dummy bonding layer 81 is formed on the first dielectric bonding layer 18 of the first semiconductor structure 1, and is spaced apart from the second dielectric bonding layer 27 of the second semiconductor structure 2. The optional dummy bonding layer 81 may be made of, for example, but not limited to, silicon oxide (SiO₂). The optional dummy element 82 is formed on the optional dummy bonding layer 81. In some embodiments, the optional dummy element 82 is spaced apart from the second semiconductor structure 2. The optional dummy element 82 may be made of, for example, but not limited to, silicon (Si), and is capable of dissipating heat so as to prevent the first semiconductor structure 1 and/or the second semiconductor structure 2 from being damaged in a subsequent manufacturing process. In some embodiments, the optional dummy element 82 may be, for example, but not limited to, a dummy die. The dielectric layer 83 is formed to fill a gap between the second semiconductor structure 2 and a stack of the optional dummy bonding layer 81 and the optional dummy element 82. The dielectric layer 83 may be made of, for example, but not limited to, an oxide-based material (i.e., silicon oxide).

Referring to FIG. 1 and the example illustrated in FIG. 11, the method 100 then proceeds to step S06, where a second carrier wafer 32 is connected to the structure shown in FIG. 10 through a fusion bonding process. The second carrier wafer 32 is generally similar to the first carrier wafer 31, and may include a second base 321, a fusion bonding layer 322 and a plurality of second alignment marks 323. The second alignment marks 323 of the second carrier wafer 32 are disposed in the fusion bonding layer 322 of the second carrier wafer 32, and are spaced apart from each other. The respective materials for the second base 321, the fusion bonding layer 322, and the second alignment marks 323 of the second carrier wafer 32 may be the same as or similar to those for the first base 311, the fusion bonding layer 312, and the first alignment marks 313 of the first carrier wafer 31, and thus details thereof are omitted for the sake of brevity. After this step, the semiconductor package device 200 is obtained.

In some embodiments, when the fusion bonding layer 11 of the first semiconductor structure 1 includes conductive bonding features and/or the fusion bonding layer 312 of the first carrier wafer 31 includes conductive bonding features, step S03 (i.e., the purification process) may be performed on the conductive bonding features of the fusion bonding layer 11 and/or the fusion bonding layer 312, so as to permit metal oxide which may be formed on the conductive bonding features of the fusion bonding layer 11 and/or the fusion bonding layer 312 to be reduced to pure metal, before the fusion bonding layer 11 of the first semiconductor structure 1 is bonded to the fusion bonding layer 312 of the first carrier wafer 31. Similarly, in some embodiments, when the fusion bonding layer 322 of the second carrier wafer 32 includes conductive bonding features, step S03 (i.e., the purification process) may be performed on the conductive bonding features of the fusion bonding layer 322, so as to permit metal oxide which may be formed on the conductive bonding features of the fusion bonding layer 322 to be reduced to pure metal, before the structure shown in FIG. 10 is bonded to the fusion bonding layer 322 of the second carrier wafer 32.

In this disclosure, by performing a purification process to purify conductive bonding features (e.g., made of copper (Cu)) of each of two semiconductor structures to be bonded together to form a SoIC, metal oxide (e.g., CuO, Cu₂O, or a combination thereof) formed on each of the conductive bonding features may be efficiently reduced to pure metal (e.g., Cu), which is conducive to avoiding formation of defects (e.g., opening or delamination) at a bonding interface between the semiconductor structures, to increasing a bonding strength of the bonding interface therebetween, and to increasing a production yield of the SoIC. In addition, in the purification process, the amount of hydroxide ions (OH⁻) formed on a dielectric bonding layer of each of the semiconductor structures can be increased sufficiently to further enhance the bonding strength of the bonding interface between the semiconductor structures. The purification process may be performed using an acidic reactant (e.g., an acid) to reduce the metal oxide to pure metal, and an alkaline reactant (e.g., alkaline water, an alkaline aqueous solution, or a combination thereof) to increase the hydroxide ions (OH⁻) formed on the dielectric bonding layer of each of the semiconductor structures.

In accordance with some embodiments of the present disclosure, a method for manufacturing a semiconductor package device includes: forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer; treating the first semiconductor structure and the second semiconductor structure with an acidic reactant including an acid, so that metal oxide formed on the first conductive bonding feature and metal oxide formed on the second conductive bonding feature are reduced to pure metal; and bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

In accordance with some embodiments of the present disclosure, the acid includes formic acid, acetic acid, hydrochloric acid, sulfuric acid, or combinations thereof.

In accordance with some embodiments of the present disclosure, the acidic reactant has a hydrogen ion concentration ranging from about 10⁻³ mol/L to about 10⁻⁴ mol/L.

In accordance with some embodiments of the present disclosure, the acidic reactant is introduced for a time period ranging from about 30 seconds to about 120 seconds.

In accordance with some embodiments of the present disclosure, a method for manufacturing a semiconductor package device further includes, after formation of the first semiconductor structure and the second semiconductor structure and before treatment of the first semiconductor structure and the second semiconductor structure with the acidic reactant, the first semiconductor structure and the second semiconductor structure are treated with an alkaline reactant that includes alkaline water, an alkaline solution, or a combination thereof.

In accordance with some embodiments of the present disclosure, the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

In accordance with some embodiments of the present disclosure, the alkaline reactant has a hydroxide ion concentration ranging from about 10⁻² mol/L to about 10⁻³ mol/L.

In accordance with some embodiments of the present disclosure, the alkaline reactant is introduced for a time period ranging from about 20 seconds to about 40 seconds.

In accordance with some embodiments of the present disclosure, a method for manufacturing a semiconductor package device includes: forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer; treating the first semiconductor structure and the second semiconductor structure with an acidic reactant and an alkaline reactant, so that metal oxide formed on the first conductive bonding feature and metal oxide formed on the second conductive bonding feature are reduced to pure metal by treating with the acidic reactant, and so that amount of hydroxide ions formed on the first dielectric bonding layer and the second dielectric bonding layer are increased by treating with the alkaline reactant, the acidic reactant including an acid, the alkaline reactant including alkaline water, an alkaline solution or a combination thereof; and bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

In accordance with some embodiments of the present disclosure, the first semiconductor structure and the second semiconductor structure are treated with the alkaline reactant before being treated with the acidic reactant.

In accordance with some embodiments of the present disclosure, the acid includes an organic acid, an inorganic acid, or a combination thereof.

In accordance with some embodiments of the present disclosure, the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

In accordance with some embodiments of the present disclosure, a method for manufacturing a semiconductor package device further includes: before treatment of the first semiconductor structure and the second semiconductor structure, subjecting each of the acidic reactant and the alkaline reactant to a dissociation reaction by a plasma treatment, a catalysis treatment, or a combination thereof.

In accordance with some embodiments of the present disclosure, the dissociation reaction is conducted by the plasma treatment with a plasma generation power ranging from about 40 W to about 70 W and a plasma generation frequency ranging from about 10 MHz to about 50 MHz.

In accordance with some embodiments of the present disclosure, the dissociation reaction is conducted by the catalysis treatment using a precious metal.

In accordance with some embodiments of the present disclosure, the dissociation reaction is sequentially conducted by the plasma treatment and the catalysis treatment.

In accordance with some embodiments of the present disclosure, a method for manufacturing a semiconductor package device includes: forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer; treating the first semiconductor structure and the second semiconductor structure with an alkaline reactant that includes alkaline water, an alkaline solution or a combination thereof; treating the first semiconductor structure and the second semiconductor structure, which are treated with the alkaline reactant, with an acidic reactant that includes an acid, so that metal oxide formed on the first conductive bonding feature and metal oxide formed on the second conductive bonding feature are reduced to pure metal; and bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

In accordance with some embodiments of the present disclosure, the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

In accordance with some embodiments of the present disclosure, the acid includes formic acid, acetic acid, hydrochloric acid, sulfuric acid, or combinations thereof.

In accordance with some embodiments of the present disclosure, the first semiconductor structure and the second semiconductor structure are treated in an inert gas atmosphere including nitrogen gas, argon gas, helium gas, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor package device, comprising:
forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer;
treating the first semiconductor structure and the second semiconductor structure with an acidic reactant including an acid, so that metal oxide formed on the first conductive bonding feature and metal oxide formed on the second conductive bonding feature are reduced to pure metal; and
bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

2. The method as claimed in claim 1, wherein the acid includes formic acid, acetic acid, hydrochloric acid, sulfuric acid, or combinations thereof.

3. The method as claimed in claim 1, wherein the acidic reactant has a hydrogen ion concentration ranging from 10⁻³ mol/L to 10⁻⁴ mol/L.

4. The method as claimed in claim 1, wherein the acidic reactant is introduced for a time period ranging from 30 seconds to 120 seconds.

5. The method as claimed in claim 1, further comprising, after formation of the first semiconductor structure and the second semiconductor structure and before treatment of the first semiconductor structure and the second semiconductor structure with the acidic reactant, the first semiconductor structure and the second semiconductor structure are treated with an alkaline reactant that includes alkaline water, an alkaline solution, or a combination thereof.

6. The method as claimed in claim 5, wherein the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

7. The method as claimed in claim 5, wherein the alkaline reactant has a hydroxide ion concentration ranging from 10⁻² mol/L to 10⁻³ mol/L.

8. The method as claimed in claim 5, wherein the alkaline reactant is introduced for a time period ranging from 20 seconds to 40 seconds.

9. A method for manufacturing a semiconductor package device, comprising:
forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer;
treating the first semiconductor structure and the second semiconductor structure with an acidic reactant and an alkaline reactant, so that metal oxide formed on the first conductive bonding feature and metal oxide formed on the second conductive bonding feature are reduced to pure metal by treating with the acidic reactant, and so that an amount of hydroxide ions formed on the first dielectric bonding layer and the second dielectric bonding layer are increased by treating with the alkaline reactant, the acidic reactant including an acid, the alkaline reactant including alkaline water, an alkaline solution or a combination thereof; and
bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

10. The method as claimed in claim 9, wherein the first semiconductor structure and the second semiconductor structure are treated with the alkaline reactant before being treated with the acidic reactant.

11. The method as claimed in claim 9, wherein the acid includes an organic acid, an inorganic acid, or a combination thereof.

12. The method as claimed in claim 9, wherein the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

13. The method as claimed in claim 9, further comprising, before treatment of the first semiconductor structure and the second semiconductor structure, subjecting each of the acidic reactant and the alkaline reactant to a dissociation reaction by a plasma treatment, a catalysis treatment, or a combination thereof.

14. The method as claimed in claim 13, wherein the dissociation reaction is conducted by the plasma treatment with a plasma generation power ranging from 40 W to 70 W and a plasma generation frequency ranging from 10 MHz to 50 MHz.

15. The method as claimed in claim 13, wherein the dissociation reaction is conducted by the catalysis treatment using a precious metal.

16. The method as claimed in claim 13, wherein the dissociation reaction is sequentially conducted by the plasma treatment and the catalysis treatment.

17. A method for manufacturing a semiconductor package device, comprising:
forming a first semiconductor structure and a second semiconductor structure, the first semiconductor structure including a first dielectric bonding layer and a first conductive bonding feature disposed in the first dielectric bonding layer, the second semiconductor structure including a second dielectric bonding layer and a second conductive bonding feature disposed in the second dielectric bonding layer;
treating the first semiconductor structure and the second semiconductor structure with an alkaline reactant that includes alkaline water, an alkaline solution or a combination thereof;
treating the first semiconductor structure and the second semiconductor structure, which are treated with the alkaline reactant, with an acidic reactant that includes an acid, so that metal oxide formed on the first conductive bonding feature and metal oxide formed on the second conductive bonding feature are reduced to pure metal; and
bonding the first semiconductor structure to the second semiconductor structure by a hybrid bonding process so as to permit the first dielectric bonding layer to be bonded to the second dielectric bonding layer and to permit the first conductive bonding feature to be bonded to the second conductive bonding feature.

18. The method as claimed in claim 17, wherein the alkaline solution includes an ammonia aqueous solution, a calcium hydroxide aqueous solution, a barium hydroxide aqueous solution, a strontium hydroxide aqueous solution, a thallium hydroxide aqueous solution, or combinations thereof.

19. The method as claimed in claim 17, wherein the acid includes formic acid, acetic acid, hydrochloric acid, sulfuric acid, or combinations thereof.

20. The method as claimed in claim 17, wherein the first semiconductor structure and the second semiconductor structure are treated in an inert gas atmosphere including nitrogen gas, argon gas, helium gas, or combinations thereof.
